(19) United States
(12) Patent Application Publication
(10) Pub. No.: US 2026/0095132 A1
(43) Pub. Date: Apr. 2, 2026

(54) ADAPTIVE BIAS CURRENT CONTROL IN ENVELOPE TRACKING POWER AMPLIFIER DEVICES, SYSTEMS, AND METHODS

(71) Applicant: pSemi Corporation, San Diego, CA (US)

(72) Inventors: James Francis McElwee, Austin, TX (US); Yuan Wei, Arlington Heights, IL (US)

(21) Appl. No.: 18/900,381

(22) Filed: Sep. 27, 2024

(51) Int. Cl. H03F 3/24; H04B 1/04

(52) U.S. Cl. CPC H03F 3/245; H04B 1/04; H03F 2200/451

(57) ABSTRACT

An RF circuit is disclosed that may include a driver stage. The driver stage may include a gate bias circuit configured to receive a variable voltage supply signal; and an amplifier stage comprising a FET, wherein the gate bias circuit is configured to adaptively convert the variable voltage supply signal into a bias signal. The RF circuit may further include a circuit component configured to combine the bias signal and a radio frequency input signal to generate a combined signal, and wherein the amplifier stage is configured to receive the combined signal at a gate of the FET and to produce an intermediate output, and wherein the gate bias circuit is configured to generate the bias signal such that the bias signal increases as the variable voltage supply signal decreases to compensate for a tendency of a current through the FET to decrease as the variable voltage supply signal decreases.

### BACKGROUND

This disclosure relates to electronic radio frequency (RF) circuits, and more particularly to envelope tracking power amplifier methods, systems, and devices.

The use of envelope tracking is a common way to modulate the voltage supply of a power amplifier in RF applications, such as wireless communications using third generation (3G) through fifth generation (5G) technologies. In these and other applications, it is desirable that a gain of the power amplifier remain relatively constant over an operating range of the voltage supply. Gain dispersion is a measure of the variation in gain over an operating range of the voltage supply, and it may be desirable for gain dispersion to reflect that the gain exhibits variation that remains within specified bounds over a range of supply voltage.

Power amplifiers fabricated from certain materials and/or using certain methods, such as Gallium Arsenide (GaAs) heterojunction bipolar transistors (HBTs), are known to have satisfactory gain dispersion in many applications of interest. However, such power amplifiers have a drawback that they may be overly expensive for a given application when measured in cost per unit area. Using lower-cost materials and techniques for fabrication, such as the use of silicon-on-insulator (SOI) laterally double-diffused metal-oxide semiconductor (LDMOS) technologies, can save on cost while beneficially adding functionality and features compared to higher-cost materials and fabrication techniques, but there are drawbacks. For example, SOI/LDMOS devices can suffer from poor output conductance, particularly for devices having shorter channel lengths that are desirable for good RF performance. Variation in current as supply voltage varies can lead to unacceptably high gain dispersion.

In order to reap the benefits of gain stages in a power amplifier that use lower cost materials and fabrication techniques, new solutions and circuits are needed to maintain gain dispersion in a desirable range.

### SUMMARY

Embodiments of the present disclosure include systems, methods, and devices for adaptive bias current control in envelope tracking power amplifiers.

In some aspects, an RF circuit is disclosed. In some embodiments, the RF circuit includes a driver stage. In some embodiments, the driver stage includes a gate bias circuit configured to receive a variable voltage supply signal; and an amplifier stage comprising a field effect transistor (FET), wherein the gate bias circuit is configured to adaptively convert the variable voltage supply signal into a bias signal. The RF circuit may further include a circuit component configured to combine the bias signal and a radio frequency input signal to generate a combined signal, and wherein the amplifier stage is configured to receive the combined signal at a gate of the FET and to produce an intermediate output, and wherein the gate bias circuit is configured to generate the bias signal such that the bias signal increases as the variable voltage supply signal decreases to compensate for a tendency of a current through the FET to decrease as the variable voltage supply signal decreases.

In some aspects, a wireless communication device is disclosed. In some embodiments, the wireless communication device includes a power amplifier. The power amplifier may include driver stage configured to receive a variable voltage supply signal. The driver stage may include a gate bias circuit configured to receive the variable voltage supply signal; an amplifier stage comprising a first FET, wherein the gate bias circuit is further configured to adaptively convert the variable voltage supply signal into a bias signal; and a circuit component configured to combine the bias signal and a radio frequency input signal to generate a combined signal, wherein the amplifier stage is configured to receive the combined signal at a gate of the first FET and to produce an intermediate output. The power amplifier may further include a power amplifier stage following the driver stage, wherein the power amplifier stage is configured to generate an amplified signal based on the intermediate output.

In some aspects, a method of operating a wireless communication device is disclosed. In some embodiments, wireless communication device includes a driver stage. The driver stage may include a gate bias circuit; and an amplifier stage comprising a common source (CS) FET, and a circuit component. The method may include receiving, by the gate bias circuit, a variable voltage supply signal; adaptively generating, by the gate bias circuit, a bias signal based on the variable voltage supply signal; combining, by the circuit component, the bias signal and a radio frequency input signal to generate a combined signal; receiving, at a gate of the CS FET, the combined signal; and generating a first output signal.

The scope of the present disclosure is defined by the claims, which are incorporated into this section by reference. A more complete understanding of embodiments of the present disclosure will be afforded to those skilled in the art, as well as a realization of additional advantages thereof, by a consideration of the following detailed description of one or more embodiments. Reference will be made to the appended sheets of drawings that will first be described briefly.

### DESCRIPTION OF THE DRAWINGS

FIG. 1 illustrates an example of a power amplifier, in accordance with one or more embodiments of the present disclosure.

FIG. 2 illustrates an example driver stage, in accordance with one or more embodiments of the present disclosure.

FIG. 3 illustrates an example desired input to a gate of an amplifier stage as a function of variable voltage supply signal, in accordance with one or more embodiments of the present disclosure.

FIG. 4 illustrates an example bias circuit, in accordance with one or more embodiments of the present disclosure.

FIG. 5 illustrates another example bias circuit, in accordance with one or more embodiments of the present disclosure.

FIG. 6 illustrates an example of a circuit, in accordance with one or more embodiments of the present disclosure.

FIG. 7 illustrates an architecture of a wireless communication device, in accordance with one or more embodiments of the present disclosure.

FIG. 8 is a method of operating a wireless communication device, in accordance with one or more embodiments of the present disclosure.

Embodiments of the present disclosure and their advantages are best understood by referring to the detailed description that follows. It is noted that sizes of various components and distances between these components are not drawn to scale in the figures. It should be appreciated that like reference numerals are used to identify like elements illustrated in one or more of the figures.

### DETAILED DESCRIPTION

The present disclosure encompasses novel circuits, architectures, systems, and methods that more effectively and efficiently address the configuration and operation of RF power amplifier circuits. It will be appreciated that various improvements disclosed herein encompass innovative circuits, hardware components, architectures, and related logic that are applicable to applications beyond RF power amplifier circuits.

Power amplifier systems, methods, and devices are presented herein that provide envelope tracking power amplification with low gain dispersion at reasonable cost. In some embodiments, a “hybrid” power amplifier design is employed in which a driver stage is followed by a power amplifier stage, and in which the driver stage is fabricated using one type of device and the power amplifier stage is fabricated using another type of device. For example, the driver stage may include SOI/LDMOS devices, and the power amplifier stage may include GaAs HBT devices. A SOI/LDMOS driver in such a power amplifier provides a number of benefits, including: improved programmability; improved integration (e.g., with Mobile Industry Processor Interface (MIPI), Power Amplifier Controllers (PACs), etc.); access to SOI/LDMOS switches (e.g., switchable RF path options, such as switchable paths between wireless cellular 2G and 5G final power amplifier stages); potential overall cost reduction; and/or bottom-side mount options for the driver stage(s), as compared to GaAs drivers which may be more difficult to mount on the bottom side. However, a SOI/LDMOS driver can have an unsatisfactory gain dispersion under typical operating conditions in which supply voltage is varying with RF signal envelope. Although GaAs HBT drivers can have satisfactory gain dispersion, such drivers do not yield many of the benefits listed above for SOI/LDMOS drivers. This disclosure provides solutions to enable the use of SOI/LDMOS drivers with satisfactory gain dispersion.

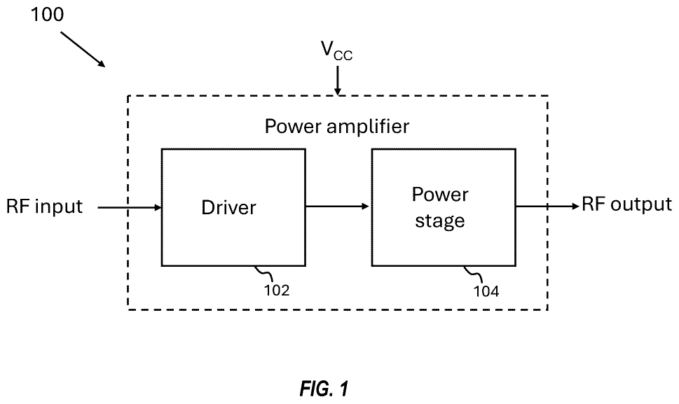

This disclosure recognizes that variation in device current as supply voltage varies can lead to unacceptably high gain dispersion. Adaptive bias control of the gate of an SOI/LDMOS device in an amplifier consisting of such SOI/LDMOS devices can mitigate variations in current, resulting in better control of gain as supply voltage varies. Presented herein are circuits to control gain-stage device gate voltages, such as in a common-source or a cascode amplifier stage, thus offsetting variations in current as supply voltage varies. These features are further explained below with respect to FIG. 1.

FIG. 1 illustrates an example of a power amplifier 100, in accordance with one or more embodiments of the present disclosure. The power amplifier 100 includes a driver stage 102 connected to a power stage 104 as shown. The power stage 104 may also be referred to as a power amplifier stage 104. The power amplifier 100 is configured to receive an RF signal and amplify the RF signal to produce an RF output, which has a greater power than the RF input. The power amplifier 100 may be used in an application in which the voltage supply signal V_{CC} is varying. For example, in a wireless communication application that uses envelope tracking, the voltage supply signal VCC may be a variable voltage supply signal that varies according to the envelope of the RF input signal. The driver stage 102 may include a SOI/LDMOS driver, and the power stage 104 may include a GaAs HBT power amplifier stage, thereby forming a “hybrid” power amplifier 100 designed to combine benefits of using a SOI/LDMOS driver with a GaAs power amplifier stage, while minimizing the drawbacks. The power amplifier stage 104 may produce an amplified version of the intermediate output signal produced by driver stage 102.

In some embodiments, the driver stage 102 may further include a switch (not shown) at the driver 102 output that switchably sends the RF signal to an amplifier designed for the cellular signal of interest. For example, the power stage 104 may include one power amplifier designed for 2G signals and another power amplifier designed for 5G signals, with 2G signals routed to the 2G amplifier and 5G signals routed to the 5G amplifier. Such embodiments are within the scope of this disclosure.

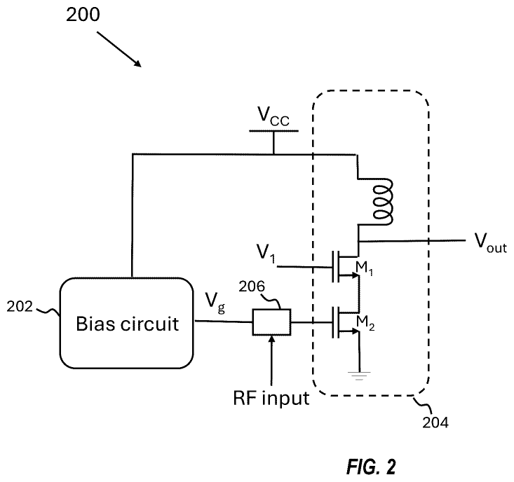

FIG. 2 illustrates an example driver stage 200, in accordance with one or more embodiments of the present disclosure. In some embodiments, the driver stage 200 may be a more detailed diagram of the driver stage 102 of FIG. 1, with Vₒᵤₜ provided as an input to the power amplifier stage 104 (thus, Vₒᵤₜ may be understood as an intermediate output in a power amplifier). As shown, the driver stage 200 includes a bias circuit 202, an amplifier stage 204, and a circuit component 206. In this embodiment, the amplifier stage 204 includes a common gate MOS transistor M₁ (e.g., a MOS field effect transistor or MOSFET) and a common source MOS transistor M₂ (e.g., a MOSFET) configured in a stacked configuration as a cascode amplifier, with an inductor L connected between M₁ and a variable voltage supply signal V_{CC}. In some embodiments, the source of M₁ is connected to the drain of M₂. In some embodiments, the bias circuit 202 receives the variable voltage supply signal VCC as an input and generates a gate voltage bias signal V_{g} as an output. (Thus, the bias circuit 202 illustrated in FIG. 2 may also be referred to as a gate bias circuit.) The gate voltage bias signal V_{g} is used to bias the gate voltage of the common source transistor M₂. An RF input, such as a signal for wireless communication, is also received and combined with voltage signal V_{g} as the gate voltage of common source transistor M₂. For example, the RF input may be input to the circuit component 206 with the output a combined signal having an RF component and a bias component provided by gate bias signal V_{g}. A bias signal V₁ determines the gate of common gate transistor M₁. In some embodiments, for example fixed supply or APT systems, bias signal V₁ may be static. In some embodiments, for example variable supply envelope tracking (ET) systems, bias signal V₁ may also be variable and may be provided by a gate bias circuit. In some embodiments, the circuit component 206 is a transformer or a DC blocking capacitor.

In another embodiment, the amplifier stage 204 alternatively does not include common gate MOSFET M₁, so amplifier stage 204 may simply be a common source amplifier that includes only MOSFET M₂. This disclosure relates generally to biasing the gate of the main amplifying transistor in an amplifier stage of a driver stage in a power amplifier. The amplifier stage may include a common source amplifier or a cascode amplifier, as examples.

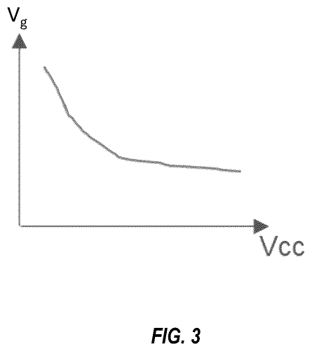

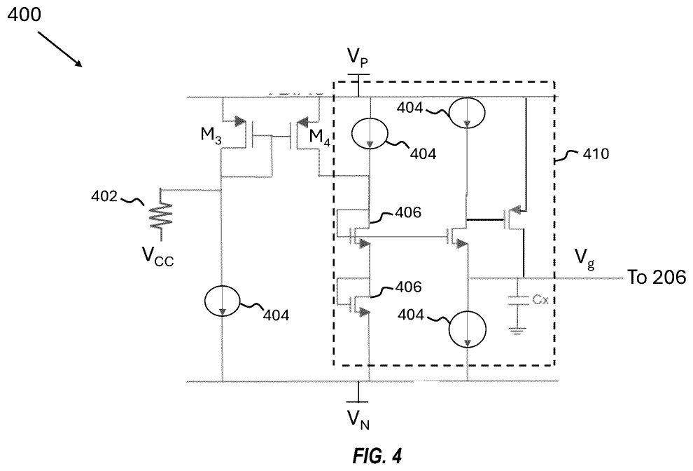

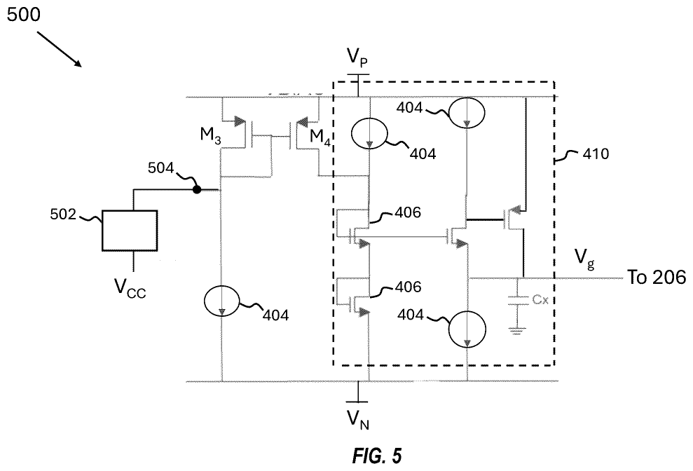

This disclosure recognizes that it is desirable for the bias circuit 202 to generate a bias signal V_{g} that tracks V_{CC} such that gain dispersion remains in an acceptable range, even with RF input signals having bandwidths greater than 100 megahertz (MHz), which may occur in cellular wireless applications, such as when certain 4G or 5G cellular bands are used. For example, this disclosure recognizes that when SOI/LDMOS devices are desirably used in bias circuit 202, these devices may be much more sensitive to variations in supply voltage V_{CC} as compared to HBT devices. According to some embodiments, as V_{CC} decreases below a threshold such as 1.5 V, there can be a disproportionately large decrease in drain-to-source current for a given DC gate voltage on the gate of common source transistor M₂. This disclosure recognizes that to mitigate these undesired effects, the gate voltage of common source transistor M₂ should be boosted in a disproportionate (non-linear) manner as VCC decreases below certain values. For example, FIG. 3 illustrates an example desired input to the gate of M₂ in FIG. 2 as a function of V_{CC}. As shown, for larger values of V_{CC}, the desired value of V_{g} should remain relatively stable. Once V_{CC} starts decreasing below a certain value, the desired value of V_{g} increases dramatically. For example, as V_{CC} drops there may be a need to compensate V_{g}, to offset or counter the natural tendency of the current to decrease as V_{CC} drops due to channel length modulation with change in drain current or output impedance. Example bias circuits that yield desirable gain dispersions and desirable voltage signal characteristics for V_{g} described above are presented in FIGS. 4 and 5 and discussed further below.

FIG. 4 illustrates an example bias circuit 400, in accordance with one or more embodiments of the present disclosure. The bias circuit may include a resistor 402 that is programmable (e.g., variable with a value that is programmable). The resistor 402 and accompanying circuit behaves as a simple voltage-to-current converter that converts supply voltage V_{CC} (e.g., as shown in FIG. 2) to a current. The circuit 400 is connected to a positive voltage rail V_{P}, such as a positive voltage supplied by a bias generator and a negative voltage rail V_{N}, such as ground or a negative bias voltage supplied by a negative bias generator, where V_{N}<V_{P}. Without being bound by theory, if V_{CC} exceeds V_{P} minus the voltage across FET M₃, the current through the resistor 402 reduces the current in M₃, until reaching 0 when the resistor current matches current source 404. After this point, with increasing V_{CC}, there will be no effect on current M₃, M₄ (both will be off).

In other words, bias circuit 400 includes FETs M₃ and M₄ that are connected in a current mirror-type configuration. Bias circuit 400 may also include DC current sources 404 as shown. The bias circuit 400 may also include diode-connected FETs 406. As current increases through M₃ (as V_{CC} decreases below VP minus the voltage drop across M3), bias current increases through resistor 402 and FET M₃, thereby also resulting in increases current through FET M₄ (via current mirroring) and diode-connected FETs 406. The bias circuit further includes a circuit 410 that includes the diode-connected FETs 406 and generates the bias volage V_{g} based on the current in M₄. The fixed currents reflected by four DC current sources 404 can change the mixture of fixed current versus current contributions due to V_{CC}-dependent bias values. For a wide modulation bandwidth, high frequency current mirroring of the current through M₃ and resistor 402 is provided. The bias circuit 400 is an example of a circuit that receives V_{CC} as an input and generates a voltage V_{g} at output that varies with V_{CC} (e.g., according to the relationship illustrated in FIG. 3). In ET systems, where V_{CC} varies with the envelope of the RF modulated signal, the gate bias Vg should track V_{CC} with little phase shift, otherwise distortion in the form of memory effects can occur. Memory effects can result when bias circuitry becomes corrupted with a distorted version of the baseband/modulation, and may result in adjacent channel leakage ratio ACLR and EVM degradation.

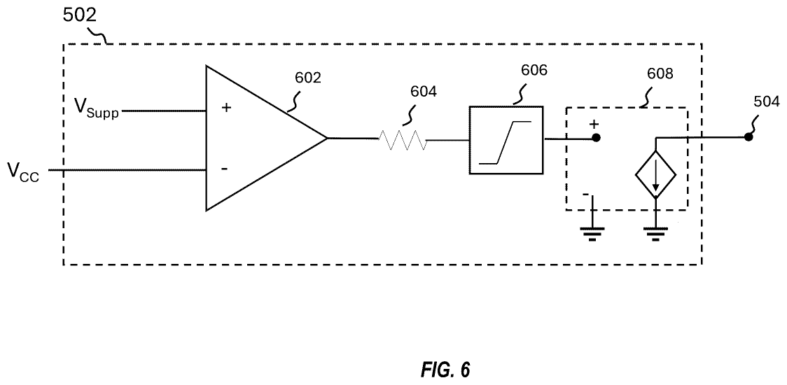

FIG. 5 illustrates another example bias circuit 500, in accordance with one or more embodiments of the present disclosure. The bias circuit 500 has a similar structure to bias circuit 400, except that the programmable resistor 402 of FIG. 4 is replaced by circuit 502. FIG. 6 illustrates an example of the circuit 502, in accordance with one or more embodiments of the present disclosure. In this embodiment, the circuit 502 includes a linear amplifier 602, a resistor 604, a limiter 606, and a voltage-controlled current source 608. In an embodiment, the resistor 604 is optional. For example, resistor 604 may not be included if amplifier 602 and/or current source 608 are close enough to ideal. In an embodiment, the limiter 606 is optional and may be included to prevent current at node or terminal 504 from increasing beyond a desired value or range. In an embodiment, the amplifier 602, the resistor 604, and the voltage-controlled current source 608 are connected in series, and a limiter 606 may or may not also be included in the series connection.

The linear amplifier 602 may receive the variable voltage supply V_{CC} and a fixed voltage Vₛᵤₚₚ and produce a difference between the two voltages at the output. The fixed voltage Vₛᵤₚₚ may be provided by a voltage supply (not shown), and the value of Vₛᵤₚₚ may be programmable (e.g., 3 V, 4V, 5V, etc.). The value of the gain of amplifier 602 may also be programmable (e.g., the gain could be 1 (unity gain), 2, 3, etc.). The limiter 606 is an example of a non-linear circuit element that may be used to shape the current profile versus V_{CC}, but other non-linear circuits may be used as alternatives. In addition, certain configurations of amplifier 602 may provide limiting functions intrinsically, such that no additional non-linear circuit element is needed. The circuit 502 is an example of a conversion of voltage(V_{CC})-to-current circuit for generating an input at node or terminal 504 for input into the rest of the bias circuit shown in FIG. 5 (which was previously described with respect to FIG. 4).

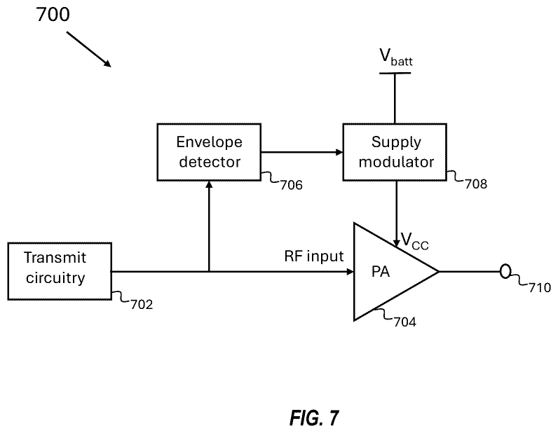

FIG. 7 illustrates an architecture of a wireless communication device 700, in accordance with one or more embodiments of the present disclosure. In this embodiment, the wireless communication device may include transmit circuitry 702 that includes conventional circuitry to convert digital data to an RF signal, such as baseband circuitry for modulating the digital data onto a baseband signal followed by RF circuitry that converts the baseband signal to an RF signal. The transmit circuitry 702 is well-known in wireless communications, and may be used to generate signals compatible with 2G, 3G, 4G, or 5G cellular communications, as examples. Other forms of wireless communications may be used, such as WiFi and satellite communications. The wireless communication device 700 further includes an envelope detector 706 and a supply modulator 708. In some embodiments, the envelope detector 706 determines a voltage supply value based on a measured envelope of the input RF signal. The wireless communication device 700 may further include a supply modulator 708 that generates a variable voltage supply signal from a stable DC voltage supply, such as a battery that produces a DC voltage output labeled as V_{batt}. The envelope detector 706 controls the voltage produced by the supply modulator 708. For example, the envelope detector 706 may employ a lookup table (LUT) in some embodiments that maps an envelope value to a desired value of V_{CC}, and the desired value of V_{CC} may be indicated to the supply modulator 708. More generally, the envelope detector 706 and the supply modulator 708 may work in conjunction to set the value of V_{CC} (a variable voltage supply signal for the PA 704).

The wireless communication device 700 may further include power amplifier (PA) 704. The PA 704 may be configured to receive an RF input signal and amplify the RF input signal to produce an output at output terminal 710. The PA 704 may be configured as power amplifier 100 in FIG. 1, with driver stage 102 being implemented using driver stage 200 in FIG. 2. The bias circuit 202 in FIG. 2 may further be implemented as bias circuit 400 in FIG. 4 or bias circuit 500 in FIG. 5. The driver stage 102 may use SOI/LDMOS devices, and the power stage (or power amplifier stage) 104 may use GaAs HBT devices. As explained herein, the driver stage 102 includes a bias circuit and an amplifier stage, such that the bias circuit produces a bias signal that tracks the variable voltage supply signal V_{CC}, leading to satisfactory gain dispersion, even when RF input signal bandwidth exceeds (or is greater than) state-of-the-art RF signal bandwidths, such as 80 MHz, 90 MHz, 100 MHz, etc. The wireless communication device 700 may further include one or more antennas (not shown) for transmitting the output from output terminal 710.

The PA 704 configured using the techniques described herein may have a desirable gain dispersion and favorable look-up table characteristics. For example, the PA 704 may have a gain dispersion of 4 dB or less where gain is measured at V_{CC}=5V and V_{CC}=1V and gain data is taken for an RF input of 10 dBm (decibels expressed on a logarithmic relative to 1 milliwatt (mW) as 0 dBm).

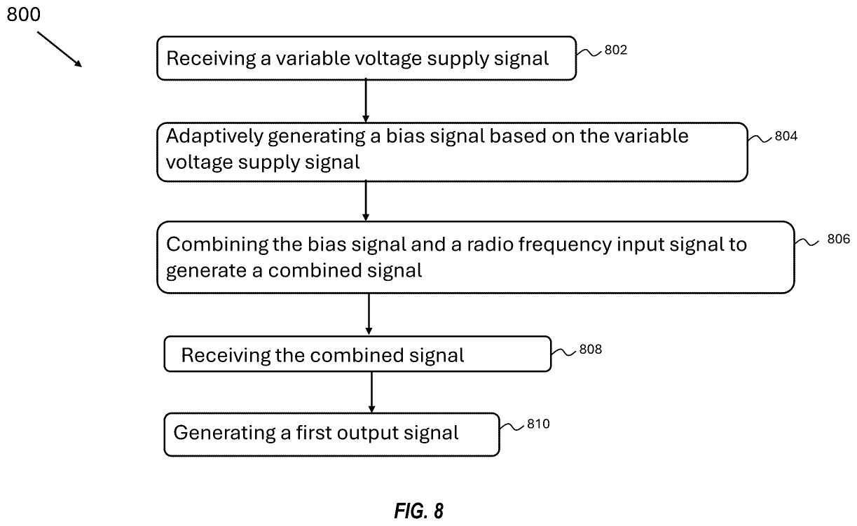

FIG. 8 is a method 800 of operating a wireless communication device, in accordance with one or more embodiments of the present disclosure. An example of such a wireless communication device to which the method 800 applies is wireless communication device 700, wherein the PA 704 includes a driver stage (such as driver stage 200) having a bias circuit (such as bias circuit 202) that provides a bias voltage signal to an amplifier circuit (such as amplifier stage 204). In step 802, a variable voltage supply signal V_{CC} is received, e.g., by a gate bias circuit 202. In step 804, a bias signal is adaptively generated based on the variable voltage supply signal to lower a gain dispersion of the power amplifier, such as PA 704. In step 806, the bias signal generated in step 804 is combined with an RF input signal to generate a combined signal, and in step 808, the combined signal is received by the amplifier circuit. Applying steps 806 and 808 to the circuit 200 in FIG. 2, circuit component 206 combines the bias signal V_{g} and the RF input, and FET M₂ receives the combined bias signal and RF input signal. In step 810, an output signal is generated by the amplifier circuit, such as at the drain of FET M₁ in FIG. 2. If amplifier circuit 204 is implemented alternatively as a common source amplifier, the output signal may be generated at the drain of a common source FET. In some embodiments, the driver stage referenced with respect to method 800 includes SOI/LDMOS devices. The method 800 may further include receiving, by a power amplifier stage following the driver stage, the output signal, and amplifying, by the power amplifier stage, the output signal to generate a signal for transmission.

Further aspects of the present disclosure include the following:
Aspect 1 includes an RF circuit comprising: a driver stage comprising: a gate bias circuit configured to receive a variable voltage supply signal; and an amplifier stage comprising a FET, wherein the gate bias circuit is configured to adaptively convert the variable voltage supply signal into a bias signal, wherein the RF circuit further comprises: a circuit component configured to combine the bias signal and a radio frequency input signal to generate a combined signal, and wherein the amplifier stage is configured to receive the combined signal at a gate of the FET and to produce an intermediate output, and wherein the gate bias circuit is configured to generate the bias signal such that the bias signal increases as the variable voltage supply signal decreases to compensate for a tendency of a current through the FET to decrease as the variable voltage supply signal decreases.
Aspect 2 includes the RF circuit of aspect 1, wherein the gate bias circuit is further configured to generate the bias signal such that the bias signal decreases in a non-linear manner as the variable voltage supply signal increases.
Aspect 3 includes the RF circuit of aspect 1, wherein the gate bias circuit comprises: a first circuit configured to convert the variable voltage supply signal into a first current; a current mirror configured to mirror the first current as a second current; and a second circuit configured to generate the bias signal based on the second current.
Aspect 4 includes the RF circuit of aspect 3, wherein the first circuit comprises a resistor connected between the variable voltage supply signal and the current mirror.
Aspect 5 includes the RF circuit of aspect 3, wherein the first circuit comprises: a first amplifier; and a voltage-controlled current source, wherein the first amplifier, and the voltage-controlled current source are connected in series, wherein the first amplifier is configured to: receive the variable voltage supply signal at a first input terminal, and receive a programmable fixed voltage signal at a second input terminal, and wherein the voltage-controlled current source is configured to generate the first current
Aspect 6 includes the RF circuit of aspect 3, further comprising: a power amplifier stage following the driver stage, wherein the power amplifier stage is configured to generate an amplified signal based on the intermediate output.
Aspect 7 includes the RF circuit of aspect 6, wherein the current mirror comprises a first plurality of FETs, wherein the second circuit comprises a second plurality of FETs, and wherein the FET, the first plurality of FETs, and the second plurality of FETs are SOI/LDMOS devices, and wherein the power amplifier stage comprises GaAs HBT devices.
Aspect 8 includes the RF circuit of aspect 3, wherein a gain dispersion of the driver stage is less than 3 decibels for the radio frequency input signal having a bandwidth of greater than 80 megahertz.
Aspect 9 includes the RF circuit of aspect 1, wherein the variable voltage supply signal is based on an envelope of the radio frequency input signal.
Aspect 10 includes the RF circuit of aspect 1, wherein the amplifier stage further comprises a second FET, wherein the FET and the second FET are in a stacked configuration, and wherein the intermediate output is produced at a drain of the second FET.
Aspect 11 includes the RF circuit of aspect 4, wherein the resistor is a programmable resistor.
Aspect 12 includes the RF circuit of aspect 5, wherein the first circuit further comprises a resistor connected in series between the first amplifier and the voltage-controlled current source.
Aspect 13 includes a wireless communication device comprising: a power amplifier comprising: a driver stage configured to receive a variable voltage supply signal, the driver stage comprising: a gate bias circuit configured to receive the variable voltage supply signal; an amplifier stage comprising a first FET, wherein the gate bias circuit is further configured to adaptively convert the variable voltage supply signal into a bias signal; and a circuit component configured to combine the bias signal and a radio frequency input signal to generate a combined signal, wherein the amplifier stage is configured to receive the combined signal at a gate of the first FET and to produce an intermediate output, wherein the power amplifier further comprises: a power amplifier stage following the driver stage, wherein the power amplifier stage is configured to generate an amplified signal based on the intermediate output.
Aspect 14 includes the wireless communication device of aspect 13, further comprising: an envelope detector circuit configured to receive the radio frequency input signal and generate an envelope signal that tracks an envelope of the radio frequency input signal; and a supply modulator configured to receive the envelope signal and generate the variable voltage supply signal based on the envelope signal.
Aspect 15 includes the wireless communication device of aspect 14, wherein the gate bias circuit is configured to generate the bias signal such that the bias signal decreases as the variable voltage supply signal increases and such that the bias signal increases as the variable voltage supply signal decreases.
Aspect 16 includes the wireless communication device of aspect 15, wherein the gate bias circuit comprises: a first circuit configured to convert the variable voltage supply signal into a first current; a current mirror configured to mirror the first current as a second current; and a second circuit configured to generate the bias signal based on the second current.
Aspect 17 includes the wireless communication device of aspect 16, wherein the first circuit comprises a resistor connected between an input configured to receive the variable voltage supply signal and the current mirror.
Aspect 18 includes the wireless communication device of aspect 16, wherein the first circuit comprises: a first amplifier; and a voltage-controlled current source, wherein the first amplifier, and the voltage-controlled current source are connected in series, wherein the first amplifier is configured to: receive the variable voltage supply signal at a first input terminal; and receive a DC supply signal at a second input terminal, and wherein the voltage-controlled current source is configured to generate the first current
Aspect 19 includes the wireless communication device of aspect 16, wherein the current mirror comprises a first plurality of FETs, wherein the second circuit comprises a second plurality of FETs, and wherein the first FET, the first plurality of FETs, and the second plurality of FETs are silicon-on-insulator SOI/LDMOS devices, and wherein the power amplifier stage comprises GaAs HBT devices.
Aspect 20 includes the wireless communication device of aspect 13, wherein the circuit component comprises a transformer or a capacitor.
Aspect 21 includes a method of operating a wireless communication device, wherein the wireless communication device comprises a driver stage comprising: a gate bias circuit; and an amplifier stage comprising a CS FET, and a circuit component, wherein the method comprises: receiving, by the gate bias circuit, a variable voltage supply signal; adaptively generating, by the gate bias circuit, a bias signal based on the variable voltage supply signal; combining, by the circuit component, the bias signal and a radio frequency input signal to generate a combined signal; receiving, at a gate of the CS FET, the combined signal; and generating a first output signal.
Aspect 22 includes the method of aspect 21, wherein the wireless communication device further comprises a power amplifier stage following the driver stage, and wherein the method further comprises: receiving, by the power amplifier stage, the first output signal; and amplifying, by the power amplifier stage, the first output signal to generate a signal for transmission.

Aspect 23 includes the method of aspect 22, wherein the driver stage comprises SOI/LDMOS devices, and wherein the power amplifier stage comprises GaAs HBT devices.

### Programmable Embodiments

Some or all aspects of the disclosure may be implemented in hardware or software, or a combination of both (e.g., programmable logic arrays). Unless otherwise specified, the algorithms included as part of the invention are not inherently related to any particular computer or other apparatus. In particular, various general purpose computing machines may be used with programs written in accordance with the teachings herein, or it may be more convenient to use a special purpose computer or special-purpose hardware (such as integrated circuits) to perform particular functions. Thus, embodiments of the invention may be implemented in one or more computer programs (i.e., a set of instructions or codes) executing on one or more programmed or programmable computer systems (which may be of various architectures, such as distributed, client/server, or grid) each comprising at least one processor, at least one data storage system (which may include volatile and non-volatile memory and/or storage elements), at least one input device or port, and at least one output device or port. Program instructions or code may be applied to input data to perform the functions described in this disclosure and generate output information. The output information may be applied to one or more output devices in known fashion.

Each such computer program may be implemented in any desired computer language (including machine, assembly, or high-level procedural, logical, or object-oriented programming languages) to communicate with a computer system, and may be implemented in a distributed manner in which different parts of the computation specified by the software are performed by different computers or processors. In any case, the computer language may be a compiled or interpreted language. Computer programs implementing some or all of the invention may form one or more modules of a larger program or system of programs. Some or all of the elements of the computer program can be implemented as data structures stored in a computer readable medium or other organized data conforming to a data model stored in a data repository.

Each such computer program may be stored on or downloaded to (for example, by being encoded in a propagated signal and delivered over a communication medium such as a network) a tangible, non-transitory storage media or device (e.g., solid state memory media or devices, or magnetic or optical media) for a period of time (e.g., the time between refresh periods of a dynamic memory device, such as a dynamic RAM, or semi-permanently or permanently), the storage media or device being readable by a general or special purpose programmable computer or processor for configuring and operating the computer or processor when the storage media or device is read by the computer or processor to perform the procedures described above. The inventive system may also be considered to be implemented as a non-transitory computer-readable storage medium, configured with a computer program, where the storage medium so configured causes a computer or processor to operate in a specific or predefined manner to perform the functions described in this disclosure.

### Fabrication Technologies & Options

The term “MOSFET”, as used in this disclosure, includes any field effect transistor (FET) having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions have been greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies such as bipolar, BiCMOS, LDMOS, BCD, GaAs HBT, GaN HEMT, GaAs pHEMT, and MESFET technologies. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

Circuits and devices in accordance with the present invention may be used alone or in combination with other components, circuits, and devices. Embodiments of the present invention may be fabricated as integrated circuits (ICs), which may be encased in IC packages and/or in modules for ease of handling, manufacture, and/or improved performance. In particular, IC embodiments of this invention are often used in modules in which one or more of such ICs are combined with other circuit blocks (e.g., filters, amplifiers, passive components, and possibly additional ICs) into one package. The ICs and/or modules are then typically combined with other components, often on a printed circuit board, to form part of an end product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

A number of embodiments of the disclosure have been described. It is to be understood that various modifications may be made without departing from the spirit and scope of the disclosure. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the disclosure, which is defined by the scope of the following claims, and that other embodiments are within the scope of the claims. In particular, the scope of the disclosure includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

What is claimed is:

1. A radio frequency (RF) circuit comprising:
a driver stage comprising:
a gate bias circuit configured to receive a variable voltage supply signal; and
an amplifier stage comprising a field effect transistor (FET),
wherein the gate bias circuit is configured to adaptively convert the variable voltage supply signal into a bias signal,
wherein the RF circuit further comprises:
a circuit component configured to combine the bias signal and a radio frequency input signal to generate a combined signal, and
wherein the amplifier stage is configured to receive the combined signal at a gate of the FET and to produce an intermediate output, and
wherein the gate bias circuit is configured to generate the bias signal such that the bias signal increases as the variable voltage supply signal decreases to compensate for a tendency of a current through the FET to decrease as the variable voltage supply signal decreases.

2. The RF circuit of claim 1, wherein the gate bias circuit is further configured to generate the bias signal such that the bias signal decreases in a non-linear manner as the variable voltage supply signal increases.

3. The RF circuit of claim 1, wherein the gate bias circuit comprises:
a first circuit configured to convert the variable voltage supply signal into a first current;
a current mirror configured to mirror the first current as a second current; and
a second circuit configured to generate the bias signal based on the second current.

4. The RF circuit of claim 3,
wherein the first circuit comprises a resistor connected between the variable voltage supply signal and the current mirror.

5. The RF circuit of claim 3, wherein the first circuit comprises:
a first amplifier; and
a voltage-controlled current source,
wherein the first amplifier and the voltage-controlled current source are connected in series,
wherein the first amplifier is configured to:
receive the variable voltage supply signal at a first input terminal, and
receive a programmable fixed voltage signal at a second input terminal, and
wherein the voltage-controlled current source is configured to generate the first current.

6. The RF circuit of claim 3, further comprising:
a power amplifier stage following the driver stage, wherein the power amplifier stage is configured to generate an amplified signal based on the intermediate output.

7. The RF circuit of claim 6, wherein the current mirror comprises a first plurality of FETs, wherein the second circuit comprises a second plurality of FETs, and wherein the FET, the first plurality of FETs, and the second plurality of FETs are silicon-on-insulator laterally double-diffused metal oxide semiconductor (SOI/LDMOS) devices, and wherein the power amplifier stage comprises gallium arsenide heterojunction bipolar transistor (GaAs HBT) devices.

8. The RF circuit of claim 3, wherein a gain dispersion of the driver stage is less than 3 decibels for the radio frequency input signal having a bandwidth of greater than 80 megahertz.

9. The RF circuit of claim 1, wherein the variable voltage supply signal is based on an envelope of the radio frequency input signal.

10. The RF circuit of claim 1, wherein the amplifier stage further comprises a second FET, wherein the FET and the second FET are in a stacked configuration, and wherein the intermediate output is produced at a drain of the second FET.

11. The RF circuit of claim 4, wherein the resistor is a programmable resistor.

12. The RF circuit of claim 5, wherein the first circuit further comprises a resistor connected in series between the first amplifier and the voltage-controlled current source.

13. A wireless communication device comprising:
a power amplifier comprising:
a driver stage configured to receive a variable voltage supply signal, the driver stage comprising:
a gate bias circuit configured to receive the variable voltage supply signal;
an amplifier stage comprising a first field effect transistor (FET), wherein the gate bias circuit is further configured to adaptively convert the variable voltage supply signal into a bias signal; and
a circuit component configured to combine the bias signal and a radio frequency input signal to generate a combined signal, wherein the amplifier stage is configured to receive the combined signal at a gate of the first FET and to produce an intermediate output,
wherein the power amplifier further comprises:
a power amplifier stage following the driver stage, wherein the power amplifier stage is configured to generate an amplified signal based on the intermediate output.

14. The wireless communication device of claim 13, further comprising:
an envelope detector circuit configured to receive the radio frequency input signal and generate an envelope signal that tracks an envelope of the radio frequency input signal; and
a supply modulator configured to receive the envelope signal and generate the variable voltage supply signal based on the envelope signal.

15. The wireless communication device of claim 14,
wherein the gate bias circuit is configured to generate the bias signal such that the bias signal decreases as the variable voltage supply signal increases and such that the bias signal increases as the variable voltage supply signal decreases.

16. The wireless communication device of claim 15, wherein the gate bias circuit comprises:
a first circuit configured to convert the variable voltage supply signal into a first current;
a current mirror configured to mirror the first current as a second current; and
a second circuit configured to generate the bias signal based on the second current.

17. The wireless communication device of claim 16, wherein the first circuit comprises a resistor connected between an input configured to receive the variable voltage supply signal and the current mirror.

18. The wireless communication device of claim 16, wherein the first circuit comprises:
a first amplifier; and
a voltage-controlled current source,
wherein the first amplifier and the voltage-controlled current source are connected in series,
wherein the first amplifier is configured to:
receive the variable voltage supply signal at a first input terminal; and
receive a programmable fixed voltage signal at a second input terminal, and
wherein the voltage-controlled current source is configured to generate the first current.

19. The wireless communication device of claim 16, wherein the current mirror comprises a first plurality of FETs, wherein the second circuit comprises a second plurality of FETs, and wherein the first FET, the first plurality of FETs, and the second plurality of FETs are silicon-on-insulator laterally double-diffused metal oxide semiconductor (SOI/LDMOS) devices, and wherein the power amplifier stage comprises gallium arsenide heterojunction bipolar transistor (GaAs HBT) devices.

20. The wireless communication device of claim 13, wherein the circuit component comprises a transformer or a capacitor.

21. A method of operating a wireless communication device, wherein the wireless communication device comprises:
a driver stage comprising:
a gate bias circuit; and
an amplifier stage comprising a common source (CS) field effect transistor (FET), and
a circuit component,
wherein the method comprises:
receiving, by the gate bias circuit, a variable voltage supply signal;
adaptively generating, by the gate bias circuit, a bias signal based on the variable voltage supply signal;
combining, by the circuit component, the bias signal and a radio frequency input signal to generate a combined signal;
receiving, at a gate of the CS FET, the combined signal; and
generating a first output signal.

22. The method of claim 21, wherein the wireless communication device further comprises a power amplifier stage following the driver stage, and wherein the method further comprises:
receiving, by the power amplifier stage, the first output signal; and
amplifying, by the power amplifier stage, the first output signal to generate a signal for transmission.

23. The method of claim 22, wherein the driver stage comprises silicon-on-insulator laterally double-diffused metal oxide semiconductor (SOI/LDMOS) devices, and wherein the power amplifier stage comprises gallium arsenide heterojunction bipolar transistor (GaAs HBT) devices.
